(19) United States
(12) Patent Application Publication
(10) Pub. No.: US 2013/0099846 A1
(43) Pub. Date: Apr. 25, 2013

(54) DRIVING CIRCUIT, SEMICONDUCTOR DEVICE HAVING DRIVING CIRCUIT, AND SWITCHING REGULATOR AND ELECTRONIC EQUIPMENT USING DRIVING CIRCUIT AND SEMICONDUCTOR DEVICE

(71) Applicant: Shohtaroh Sohma, Hyogo (JP)

(72) Inventor: Shohtaroh Sohma, Hyogo (JP)

(73) Assignee: RICOH COMPANY, LTD., Tokyo (JP)

(21) Appl. No.: 13/394,230

(22) PCT Filed: Jul. 1, 2011
(86) PCT No.: PCT/JP2011/065647

§ 371 Date: Mar. 5, 2012

(30) Foreign Application Priority Data
Jul. 8, 2010 (JP) 2010-155792

(51) Int. Cl. H03L 5/00

(52) U.S. Cl. CPC H03L 5/00
USPC 327/333

(57) ABSTRACT

Disclosed is a driving circuit that includes a switching element configured to be connected between an input terminal and an output node; a first power supply circuit configured to generate a first voltage; and a first driving circuit configured to drive the switching element with an output thereof using a voltage of the output node as a reference negative-side power supply voltage and the first voltage as a positive-side power supply voltage. The voltage of the output node is used as a reference negative-side power supply voltage of the first power supply.

### TECHNICAL FIELD

The present invention relates to a driving circuit technology applied to a switching regulator and, in particular, to a driving circuit using N-channel MOSFETs or NPN transistors as switching elements, a semiconductor device having the driving circuit, and a switching regulator and electronic equipment using the driving circuit and the semiconductor device.

### BACKGROUND ART

Up until now, P-channel MOSFETs or PNP transistors have been generally used as switching elements of driving circuits. However, it has been known that the P-channel MOSFETs or PNP transistors, which are brought into a conduction state by the movement of a hole, have lower driving performance than N-channel MOSFETs or NPN transistors.

However, an improvement in the driving performance requires an increase in the sizes of the P-channel MOSFETs or PNP transistors, which gives rise to the problems of a difficulty in their downsizing and an increase in their manufacturing costs. In order to address the problems, there has been known a method in which voltage higher than or equal to input voltage is generated using a bootstrap technique and N-channel MOSFETs or NPN transistors are turned on/off as driving elements.

FIG. 1 is a diagram showing a conventional example of a switching regulator using a driving circuit according to the bootstrap technique. FIG. 2 is a diagram showing an example of the operating voltages and the current waveform of the switching regulator shown in FIG. 1.

In FIG. 1, M1 stands for a switching element (N-channel MOSFET), 10 stands for a driving circuit, VR20 stands for a constant-voltage circuit, D1 stands for a rectification diode, D2 stands for a bootstrap diode, L1 stands for an inductor, LX stands for a connection node, VH stands for power supply voltage, VBST stands for voltage, C0 stands for a capacitor, C1 stands for a bootstrap capacitor, CP1 stands for an input signal for periodically switching the switching element M1 (pulse signal from a PWM circuit (not shown)), and Vout stands for output voltage.

In the switching regulator shown in FIG. 1, when the switching element M1 serving as the N-channel MOSFET is turned off, the voltage of the connection node LX becomes negative by an amount corresponding to the forward voltage drop Vf of the rectification diode D1 (hereinafter, the connection node LX is in a “LO” state) with the current of the inductor L1. At this time, the constant-voltage circuit VR20 charges the bootstrap capacitor C1 via the bootstrap diode D2.

Further, when the switching element M1 is turned on, the voltage of the connection node LX becomes the voltage dropping from the power supply voltage VH by an amount (the on-resistance of the switching element M1×the current of the inductor L1) (hereinafter, the connection node LX is in a “HI” state). Generally, since the on-resistance of the switching element M1 is set to be extremely low, the voltage of the connection node LX becomes nearly equal to the power supply voltage VH. At this time, the positive-side power supply voltage of the driving circuit 10 becomes the voltage VBST higher than the power supply voltage VH according to the operation of the bootstrap capacitor C1. Consequently, the voltage VBST higher than the power supply voltage VH can be supplied to the switching element M1, and the driving performance of the switching element M1 can be improved.

However, in the driving circuit shown in FIG. 1, the voltage VBST of the bootstrap capacitor C1 cannot be monitored, the forward voltage drop Vf of the diode D2 fluctuates due to the current at the charging of the bootstrap capacitor C1, and the voltage VBST of the bootstrap capacitor C1 fluctuates due to the voltage of the connection node LX when the switching element M1 is turned off.

When the switching element M1 is turned off and a period at which the voltage of the connection node LX is in the “LO” state is shortened, the charging of the bootstrap capacitor C1 becomes insufficient and the voltage VBST does not sufficiently rise (see FIG. 2). Consequently, the driving performance of the switching element M1 is degraded.

Further, if the size of the diode D2 is not set to be maximized, the current at the charging of the bootstrap capacitor C1 increases when the voltage of the connection node LX drops and a voltage drop from the constant-voltage circuit VR20 due to the diode D2 increases in a case where a switching frequency is particularly high.

Furthermore, in the switching regulator, the diode D1 is brought into a current discontinuous mode when a load is light, and there is a case that the voltage of the connection node LX does not substantially drop when the output voltage Vout is high, which in turn makes it impossible to charge the bootstrap capacitor C1.

As described above, there are the problems in the use of the bootstrap technique in that the stable supply of the voltage to the bootstrap capacitor C1 is difficult and the bootstrap capacitor C1 cannot be charged if load current is not generated particularly when a load is light and load current is not generated, with the result that the switching element M1 cannot be driven.
Patent Document 1: JP-A-2009-131062

### DISCLOSURE OF INVENTION

The present invention has been made in order to address the above problems and may provide a driving circuit capable of stably supplying voltage even in a case where the output node (connection node) of the driving circuit is maintained at high voltage and in a case where a switching frequency and the forward voltage drop Vf of a bootstrap diode are high, capable of accelerating its speed and reducing its occupied area, and capable of stably supplying power supply voltage without being influenced by the fluctuation of an oscillation frequency, a discontinuous mode, and the fluctuation of a period at which the connection node is in a “LO” state. Further, the present invention may provide a semiconductor device having the driving circuit and a switching regulator and electronic equipment having the driving circuit and the semiconductor device.

In order to achieve the object described above, the present invention employs the following configuration.

An embodiment of the present invention provides a driving circuit including a switching element configured to be connected between an input terminal and an output node; a first power supply circuit configured to generate a first voltage; and a first driving circuit configured to drive the switching element with an output thereof using a voltage of the output node as a reference negative-side power supply voltage and the first voltage as a positive-side power supply voltage. The voltage of the output node is used as a reference negative-side power supply voltage of the first power supply.

### BRIEF DESCRIPTION OF DRAWINGS

FIG. 1 is a diagram showing a conventional diode-rectification-type switching regulator using a bootstrap technique;

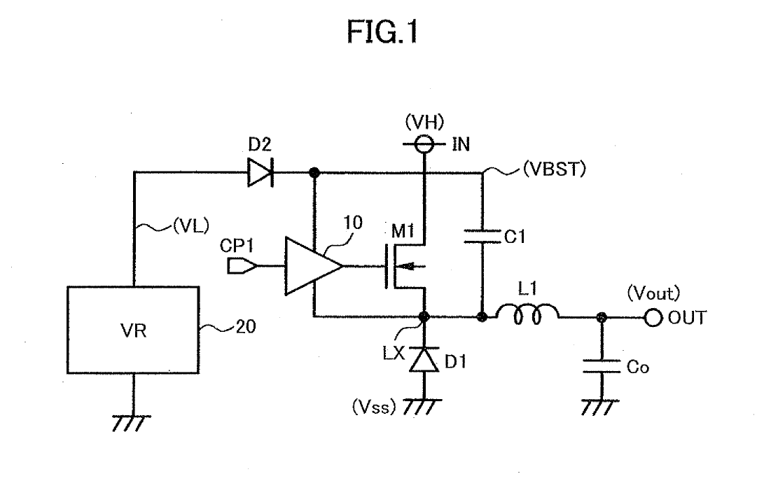

FIG. 2 is a diagram showing an example of the voltages and the current waveform of the conventional diode-rectification-type switching regulator shown in FIG. 1;

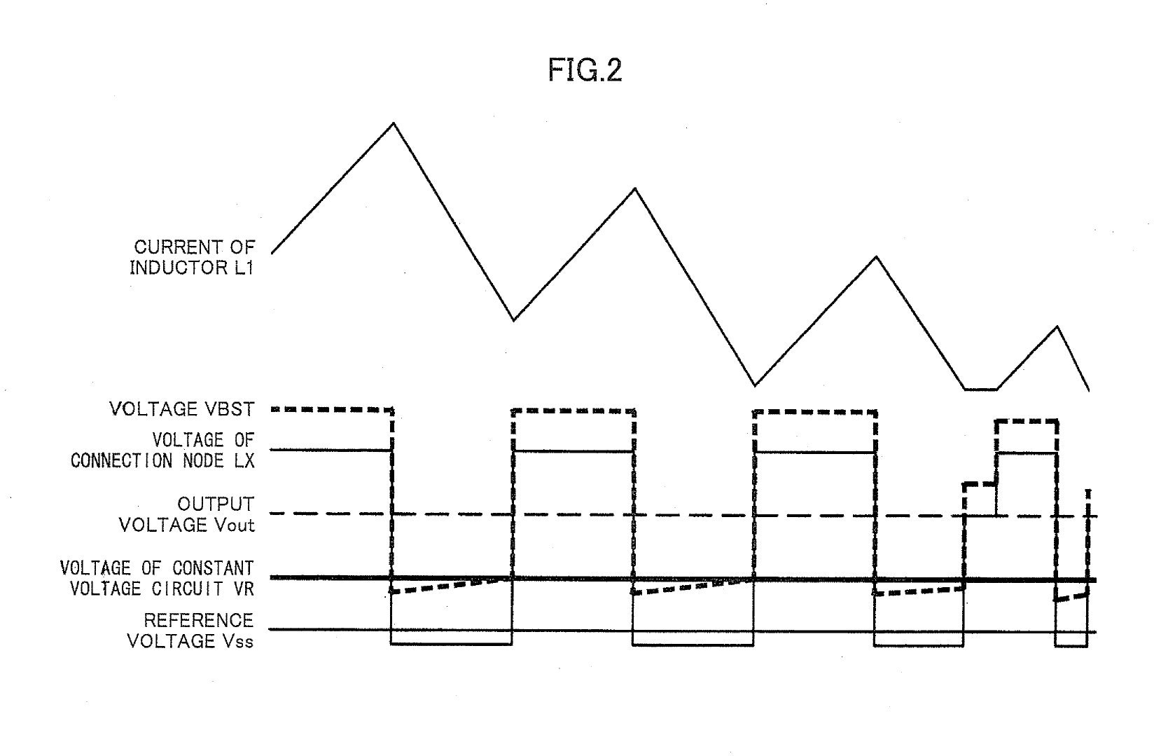

FIG. 3 is a diagram showing a diode-rectification-type switching regulator according to a first embodiment of the present invention;

FIG. 4 is a diagram showing a diode-rectification-type switching regulator according to a second embodiment of the present invention;

FIG. 5A is a diagram showing a diode-rectification-type switching regulator according to a third embodiment of the present invention;

FIG. 5B is a diagram showing a diode-rectification-type switching regulator according to a modification of the third embodiment of the present invention;

FIG. 6 is a diagram showing a diode-rectification-type switching regulator according to a fourth embodiment of the present invention;

FIG. 7A is a diagram showing a diode-rectification-type switching regulator according to a fifth embodiment of the present invention;

FIG. 7B is a diagram showing a modification in which an inverter is used instead of a comparator in the diode-rectification-type switching regulator according the fifth embodiment of the present invention;

FIG. 8 is a diagram showing a diode-rectification-type switching regulator according to a sixth embodiment of the present invention;

FIG. 9 is a diagram showing the cross section of a CMOS structure according to a seventh embodiment of the present invention; and

FIG. 10 is a diagram showing the top surface of the CMOS structure shown in FIG. 9.

### BEST MODE FOR CARRYING OUT THE INVENTION

Hereinafter, a description is specifically given, with reference to the accompanying drawings, of embodiments of a driving circuit according to the present invention using an example in which the embodiments are applied to a switching regulator.

### First Embodiment

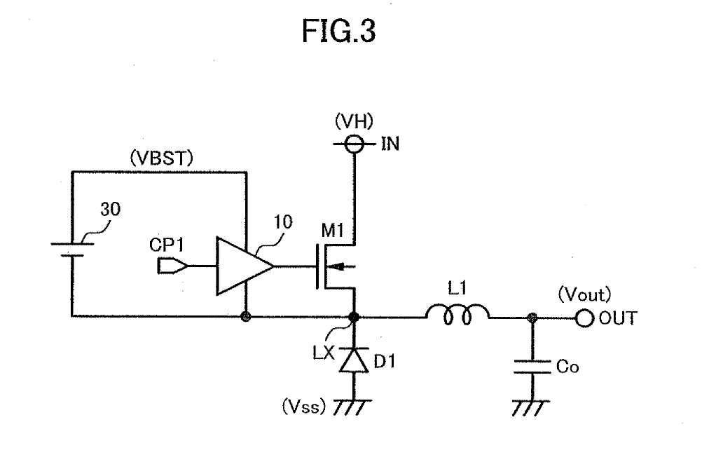

FIG. 3 is a diagram showing a diode-rectification-type switching regulator having a driving circuit according to a first embodiment of the present invention, and is an example of a step-down switching regulator of an asynchronous rectification type that converts input voltage into predetermined constant voltage and outputs the same from its output terminal.

A driving circuit unit shown in FIG. 3 is composed of a switching element M1, a rectification diode D1, a first driving circuit 10, a first power supply circuit 30, an inductor L1, and an output capacitor Co, and has an input terminal VH and an output terminal Vout.

The driving circuit according to this embodiment is composed of a semiconductor in which a high withstand voltage MOS transistor and a low withstand voltage transistor are integrated together on the same chip. To the input terminal IN is input the input voltage VH less than or equal to the withstand voltage of the high withstand voltage MOS transistor and higher than or equal to the withstand voltage of the low withstand voltage MOS transistor. For this reason, the high withstand voltage NMOS transistor is used as the switching element M1.

Note that in the switching regulator shown in FIG. 3, the respective circuits excluding the inductor L1 and the output capacitor Co may be integrated together on a single IC, or the respective circuits excluding the switching element M1 and/or the rectification diode D1, the inductor L1, and the output capacitor Co may be integrated together on the single IC as occasion demands.

The switching element M1 is connected between the input terminal IN and the cathode of the rectification diode D1, and the anode of the rectification diode D1 is connected to ground voltage Vss. Assume that a connection part between the switching element M1 and the rectification diode D1 is a connection node (“output node” of the driving circuit when considered from the viewpoint of the driving circuit) LX, the inductor L1 is connected between the connection node LX and the output terminal OUT and the output capacitor Co is connected between the output terminal OUT and the ground voltage Vss.

In this embodiment, the switching element M1 is composed of an N-channel transistor. The drain of the N-channel transistor serving as the switching element M1 is connected to the input terminal IN, the source thereof is connected to the connection node LX to which one end of the inductor L1 and the cathode of the rectification diode D1 are connected, and the gate thereof is connected to the output of the first driving circuit 10.

The first driving circuit 10 receives a pulse signal CP1 from a PWM circuit (not shown), controls the on/off of the switching element M1 in response to the input pulse signal CP1, and is composed of a low withstand voltage transistor.

The positive-side power supply of the first driving circuit 10 is connected to the first power supply circuit 30. Further, the negative-side power supply of the first driving circuit 10 is connected to the connection node LX between the source of the switching element M1 and the one end of the inductor L1.

The first power supply circuit 30 is a circuit that adds the voltage VBST lower than the withstand voltage of the low withstand voltage MOS transistor to the voltage of the connection node LX, which is the negative-side power supply serving as a reference, and that outputs the added voltage.

Next, a description is given of the operations of the diode-rectification-type switching regulator shown in FIG. 3.

(Pulse Signal CP1: Low Level→High Level)

When the pulse signal CP1 from the PWM circuit (not shown) is at a high level and the output of the first driving circuit 10 is at a high level, the switching element M1 is turned on and brought into a conduction state.

When the switching element M1 is turned on, the potential of the connection node LX becomes “HI” (high level) and the potential of the output terminal Vout also rises via the inductor L1. At this time, the potential of the connection node LX becomes nearly equal to the input voltage VH, and the gate voltage of the switching element M1 becomes higher than the potential of the connection node LX by the voltage VBST according to the first power supply circuit 30 in which the potential of the connection node LX is negative-side power supply voltage. Accordingly, the switching element M1 can be kept ON.

(Pulse Signal CP1: High Level→Low Level)

Next, when the pulse signal CP1 is at a low level and the output of the first driving circuit 10 is at a low level, the switching element M1 is turned off and brought into a cutoff state.

When the switching element M1 is turned off, current to the inductor L1 is supplied from the ground potential Vss to the inductor L1 via the rectification diode D1. Therefore, the potential of the connection node LX becomes the voltage LO lower than the ground potential Vss by the forward voltage drop of the rectification diode D1.

(Pulse Signal CP1: Low Level→High Level)

When the pulse signal CP1 is at a high level again, the output of the first driving circuit 10 is at a high level and the switching element M1 is turned on and brought into a conduction state. Accordingly, the potential of the connection node LX rises and becomes “HI” (at a high level). Hereinafter, operations similar to the above are repeatedly performed.

The first power supply circuit 30 is the circuit that outputs voltage lower than the withstand voltage of the low withstand voltage MOS transistor based on the potential (voltage of the negative-side power supply terminal) of the connection node LX. Further, the first power supply circuit 30 shares the potential of the connection node LX as the negative-side power supply voltage of the first power supply circuit 30 and the negative-side power supply voltage of the first driving circuit 10. Consequently, a potential difference (voltage) applied between the positive-side power supply terminal and the negative-side power supply terminal of the first driving circuit 10 never exceeds the output voltage VBST of the first power supply circuit 30. Therefore, the first driving circuit 10 can be composed of the low withstand voltage transistor. As described above, since the low withstand voltage transistor can be used as the constituent of the first power supply circuit 30, it is possible to reduce a chip area and achieve a high-speed response.

### Second Embodiment

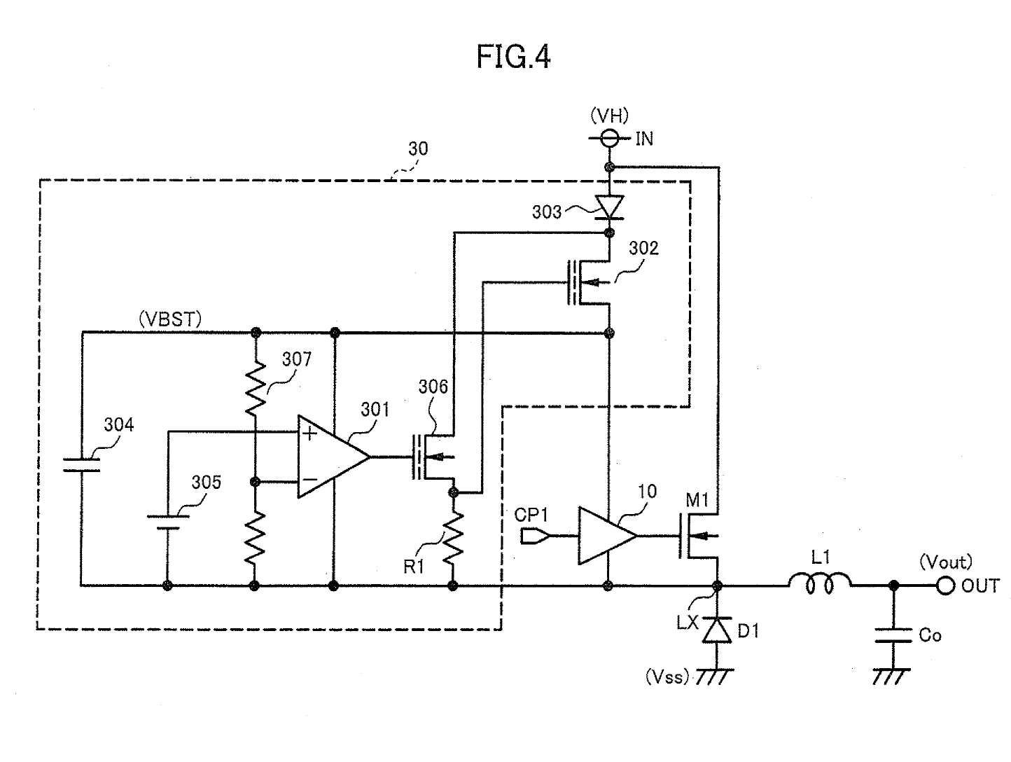

FIG. 4 is a diagram more specifically showing the first power supply circuit 30 in the diode-rectification-type switching regulator according to the first embodiment of the present invention.

In FIG. 4, the first power supply circuit 30 has an error amplifier 301 that controls the output voltage VBST, a driver 302, a rectification element 303, a smoothening capacitor 304, a reference voltage circuit 305, a level shift driver 306, a feedback resistor 307, and a resistor R1.

In this embodiment, transistors having negative threshold voltage (so-called depletion-type MOS transistors) are used as the driver 302 and the level shift driver 306. The drain terminal of the N-channel depletion transistor constituting the driver 302 is connected to the rectification element 303.

The source of the N-channel depletion transistor constituting the level shift driver 306 has a source follower structure, and is connected to the resistor R1 and the gate of the N-channel depletion transistor constituting the driver 302.

The drain terminal of the N-channel depletion transistor constituting the level shift driver 306 is connected to the drain terminal of the N-channel depletion transistor constituting the driver 302.

To the inverting input of the error amplifier 301 is input a voltage divided by the feedback resistor 307. To the non-inverting input of the error amplifier 301 is input a reference voltage by the reference voltage circuit 305. The output of the error amplifier 301 is connected to the gate of the N-channel depletion transistor constituting the level shift driver 306. The smoothening capacitor 304 is connected between the connection node LX and the output voltage VBST of the first power supply circuit 30.

Next, a description is given of the operations of the diode-rectification-type switching regulator shown in FIG. 4.

First, consideration is given to a case where no electrical charge is accumulated in the smoothening capacitor 304.

At this time, since the voltage VBST is 0 V, the potential of the positive-side power supply terminal of the error amplifier 301 is 0 V. In addition, at this time, the switching element M1 is not turned on, and the potential of the connection node LX is kept “LO” (at a low level).

Next, when voltage is applied to the input terminal IN, the rectification element 303 is biased in a forward direction and the N-channel depletion transistor constituting the driver 302 and the N-channel depletion transistor constituting the level shift driver 306 are brought into a conduction state since they have negative threshold voltage (depletion type).

It is assumed that the threshold voltages of the N-channel depletion transistor constituting the driver 302 and the N-channel depletion transistor constituting the level shift driver 306 are indicated as VTH_DEP (here, VTH_DEP<0). At this time, the source voltage of the N-channel depletion transistor constituting the level shift driver 306 becomes nearly the voltage −VTH_DEP, and the source voltage of the N-channel depletion transistor constituting the driver 302 becomes the voltage calculated by −VTH_DEP×2. With these voltages, the voltage VBST can rise up to a level at which the reference voltage circuit 305 and the error amplifier 301 can be activated.

Note that if the voltage for activating the reference voltage circuit 305 and the error amplifier 301 is insufficient, it is only necessary to increase the number of connection stages as in the configuration of the level shift driver 306. Examples of the reference voltage circuit 305 include a bandgap reference circuit and a circuit that uses the threshold voltage of a transistor.

When the error amplifier 301 and the reference voltage circuit 305 are activated, the error amplifier 301 controls the gate voltage of the N-channel depletion transistor constituting the level shift driver 306 such that the voltage obtained by dividing the voltage VBST with the feedback resistor 307 and the output voltage of the reference voltage circuit 305 have the same potential, thereby setting the voltage VBST at a desired level. At this time, the voltage VBST becomes higher than the output voltage of the error amplifier 301 by nearly the voltage calculated by −VTH_DEP×2.

When the voltage VBST exceeds voltage at which the first driving circuit 10 can be operated or when the voltage VBST exceeds voltage at which the switching element M1 can be turned on, the switching element M1 is controlled by the pulse signal CP1. When the switching element M1 is turned on, the connection node LX becomes “HI” (at a high level) and the voltage VBST becomes higher than the input voltage VH applied to the input terminal.

At this time, since the rectification element 303 is reversely biased, current does not reversely flow from the voltage VBSTS to the input voltage VH, and the gate voltage of the switching element M1 becomes higher than the voltage of the connection node LX by the voltage VBST. Consequently, the switching element M1 can be kept ON.

### Third Embodiment

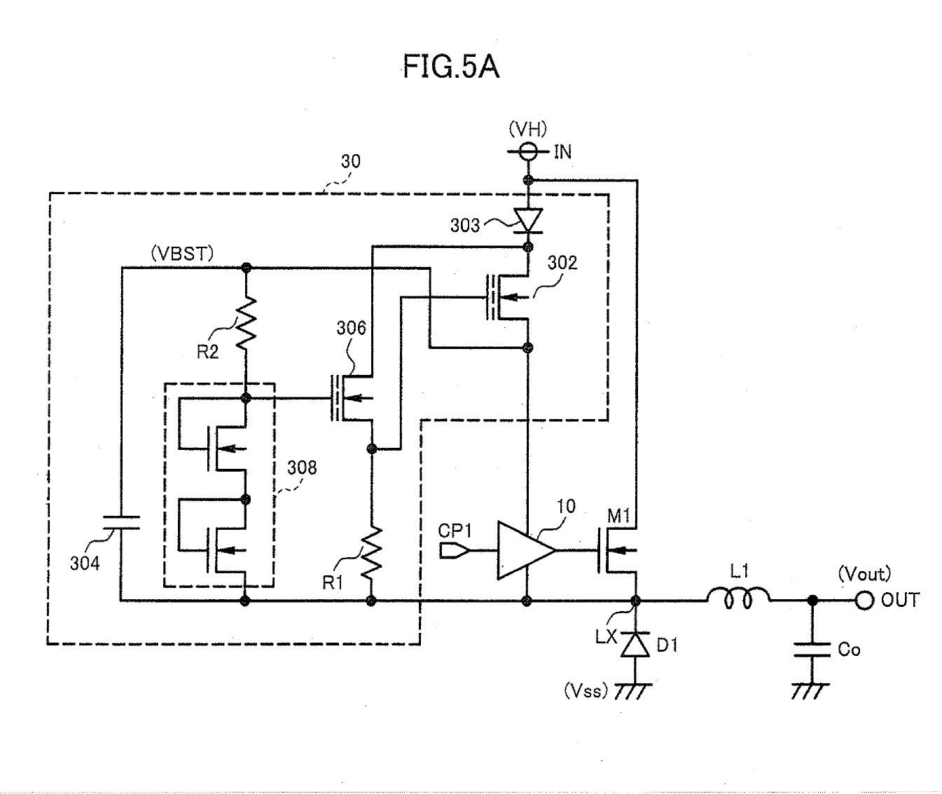

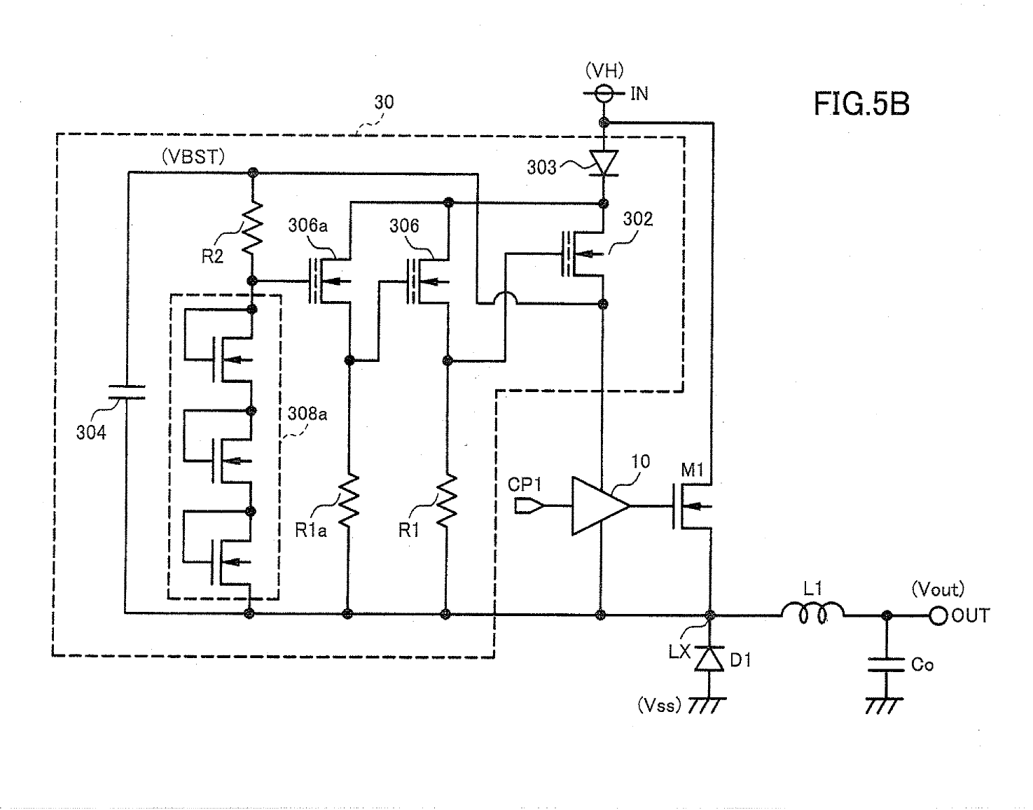

FIG. 5A is a diagram showing a third embodiment of the present invention and particularly shows a circuit realized by the elements smaller in number than the circuit shown in FIG. 4. Since the functions of the driver 302, the rectification element 303, the smoothening capacitor 304, the level shift driver 306, and the resistor R1 shown in FIG. 5A are described above with reference to FIG. 4, their duplicated descriptions are omitted here.

A resistor R2 supplies biased current to an N-channel transistor 308, and the gate voltage of the N-channel depletion transistor constituting the level shift driver 306 is applied by the multistage diode-connected N-channel transistor 308. This embodiment simplifies a circuit configuration although accuracy is slightly degraded compared with the case where the error amplifier is used as shown in FIG. 4, and enables reduction in size of the first power supply circuit 30.

In FIG. 5A, assume that the threshold voltage of the N-channel transistor 308 is indicated as VTH_ENH, the gate voltage of the N-channel depletion transistor constituting the level shift driver 306 becomes the voltage calculated by VTH_ENH×2 and the voltage VBST becomes the voltage calculated by VTH_ENH×2−VTH_DEP×2.

The voltage VBST can be controlled by changing the number of the stages of the diode-connected N-channel transistor 308 or the number of the stages of the level shift driver 306.

The adjustment of the number of the stages of the N-channel transistor 308 is performed in such a manner that the number of the series connections of the diode-connected N-channel transistor is increased or decreased. Further, the number of the stages of the level shift driver 306 can be increased in such a manner that the same connecting relationship as that established between the N-channel transistor constituting the driver 302 and the N-channel transistor constituting the level shift driver 306 is established between the N-channel transistor constituting the level shift driver 306 and an N-channel transistor constituting an additionally connected level shift driver.

FIG. 5B shows an example of a case where the number of the stages of the N-channel transistor 308 is three, the number of the stages of the driver 302 is one, and the number of the stages of the level shift drivers 306 is two and where the following relationship is established, i.e., the number of the stages of the N-channel transistor 308=the number of the stages of the driver 302+the number of the stages of the level shift drivers 306.

Further, it is desirable that the number of the stages of the N-channel transistor 308 be equal to the sum of the number of the stages of the driver 302 and the number of the stages of the level shift drivers 306. A reason for this is described below.

The threshold voltage VTH_ENH of the N-channel transistor 308 and the threshold voltage VTH_DEP of the N-channel depletion transistor are highly likely to fluctuate in the same direction from the viewpoint of a manufacturing process. In addition, the threshold voltage VTH_ENH of the N-channel transistor 308 and the threshold voltage VTH_DEP of the N-channel depletion transistor fluctuate in the same direction due to the characteristics of the transistors. Therefore, when the threshold voltage VTH_ENH of the N-channel transistor 308 fluctuates by +α, the threshold voltage VTH_DEP of the N-channel depletion transistor also fluctuates nearly by +α.

Assume that the total sum of the number of the stages of the driver 302 and the number of the stages of the level shift drivers 306 is N and the number of the stages of the diode-connected N-channel transistor 308 is M, the voltage VBST becomes the voltage calculated by VTH_ENH×N−VTH_DEP×M. Here, when the threshold voltage VTH_DEP of the N-channel depletion transistor constituting the level shift drivers 306 and the threshold voltage VTH_ENH of the diode-connected N-channel transistor 308 fluctuate by a due to temperature and a manufacturing process, the potential of the voltage VBST becomes the voltage calculated by VTH_ENH×N−NTH_DEP×M+(N−M)×α. Here, if the number of the stages N of the level shift drivers 306 is equal to the number of the stages M of the diode-connected N-channel transistor 308, the voltage VBST becomes the voltage calculated by VTH_ENH×N−VTH_DEP and the fluctuation of the threshold voltage is cancelled. For this reason, it is desirable that the number of the stages of the N-channel transistor 308 be equal to the sum of the number of the stages of the driver 302 and the number of the stages of the level shift drivers 306.

### Fourth Embodiment

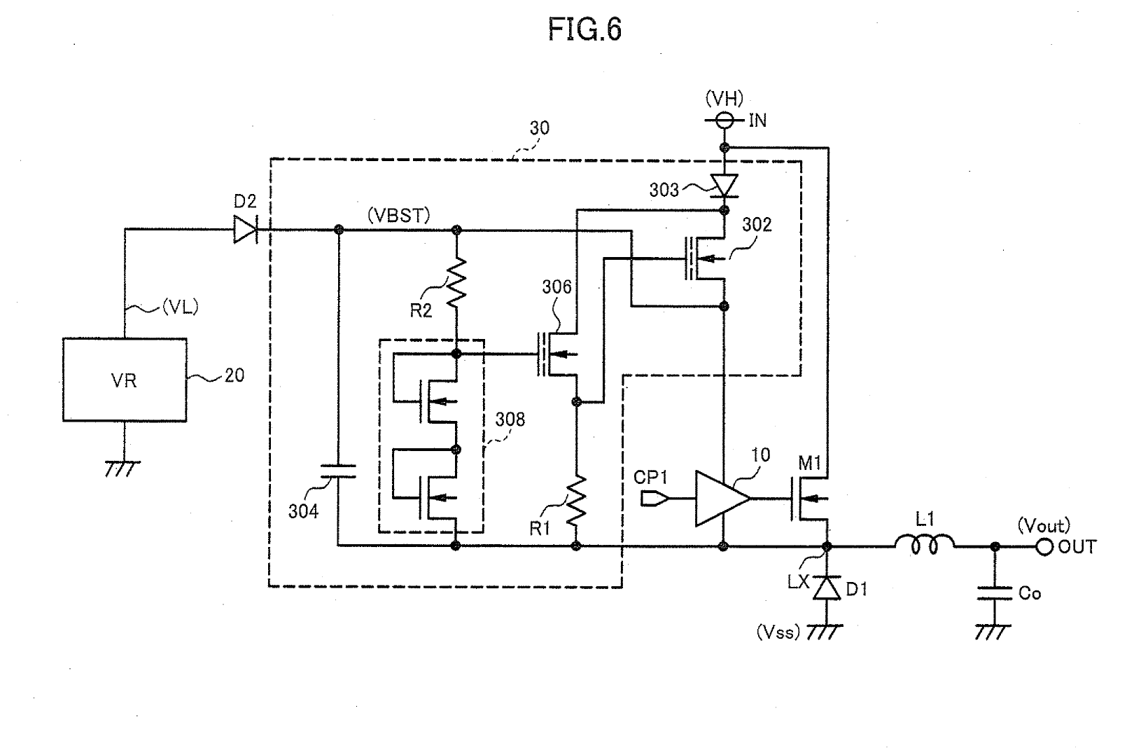

FIG. 6 is a diagram showing a fourth embodiment of the present invention and particularly shows a circuit that uses the bootstrap technique in the circuit shown in FIG. 5A.

In the circuit shown in FIG. 5A, in a case where the threshold voltage of the N-channel transistor 308 or the threshold voltage of the N-channel depletion transistor constituting the level shift driver 306 greatly fluctuates, the maximum voltage VBST is not allowed to exceed the voltage of a low withstand voltage element. Consequently, in this case, the minimum voltage VBST is reduced and the driving performance of the switching element M1 is reduced.

According to the bootstrap technique in FIG. 6, the voltage VBST is the voltage dropping from the output voltage VL of a constant voltage circuit 20 by the forward voltage drop Vf with a diode D2. In a case where the fluctuation of the voltage drop Vf is smaller than the fluctuation of the threshold voltage of the multistage-connected N-channel transistor 308 or that of the threshold voltage of the N-channel depletion transistor constituting the level shift driver 306, the voltage VBST is relatively stabilized provided that the voltage of the connection node LX is kept LOW (at a low level).

In the switching regulator, charging by the voltage VL is not completely allowed in a discontinuous mode where load current is small. Therefore, the voltage VBST is not charged, which in turn may bring about a switching failure. On the other hand, the circuit shown in FIG. 6 has both the configuration where the output voltage VL from the constant voltage circuit 20 is supplied via the bootstrap diode D2 and the driving circuit according to the third embodiment shown in FIG. 5A. Therefore, the circuit shown in FIG. 6 is free from a switching failure.

### Fifth Embodiment

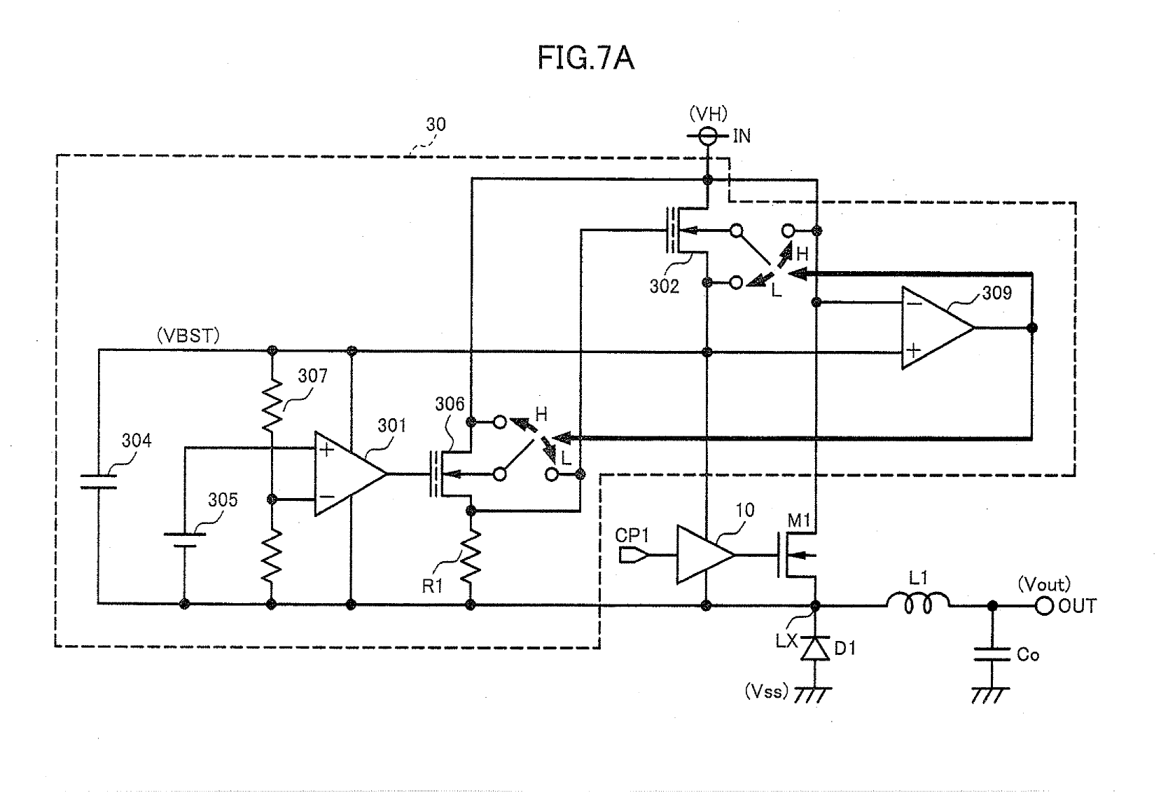

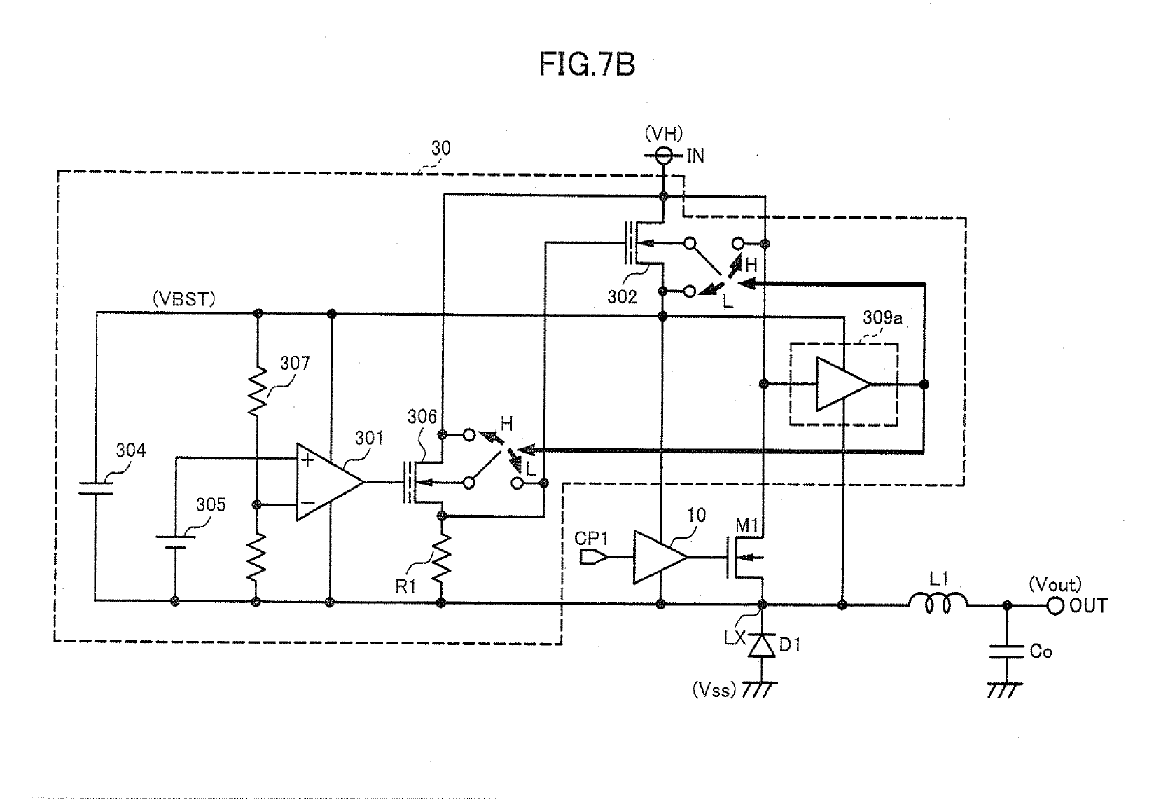

FIG. 7A is a diagram showing a fifth embodiment of the present invention and particularly shows a circuit that switches the back gate of the N-channel depletion transistor constituting the driver 302 and that of the N-channel depletion transistor constituting the level shift driver 306 in the driving circuit shown in FIG. 4.

The circuit shown in FIG. 7A is provided with a comparator 309 having its non-inverting input connected to the voltage VBST and its inverting input connected to the input voltage VH. With the output of the comparator 309, the circuit switches the back gate of the N-channel depletion transistor constituting the driver 302 and that of the N-channel depletion transistor constituting the level shift driver 306 so as not to bring a body diode into a conduction state. Thus, the circuit does not require the rectification element 303 shown in FIGS. 4 through 6.

(Modification of Fifth Embodiment)

As shown in FIG. 7B, it is also possible to use, instead of the comparator 309 shown in FIG. 7A, an inverter 309a that uses the voltage VBST as a positive-side power supply, the voltage of the connection node LX as a negative-side power supply, and the input voltage VH as an input. With this configuration, the circuit can also switch the back gate of the N-channel depletion transistor constituting the driver 302 and that of the N-channel depletion transistor constituting the level shift driver 306 so as not to bring a body diode into a conduction state. Thus, the circuit does not require the rectification element 303 as shown in FIGS. 4 through 6. While the inverting threshold of the comparator 309 is calculated by the voltage VBST=the input voltage VH, the inverting threshold of the inverter 309a is calculated by the voltage VBST=the input voltage VH+(the voltage VBST−the voltage of the connection node LX)/2. However, no problem arises in the circuit since it outputs a rectangular waveform.

### Sixth Embodiment

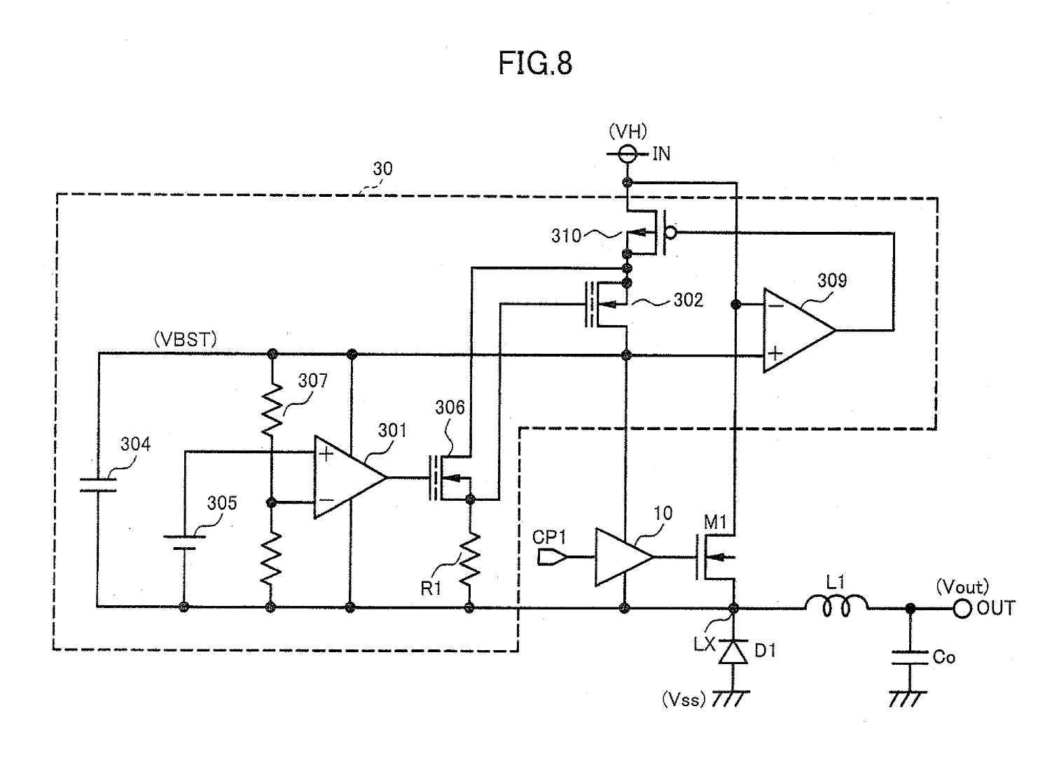

FIG. 8 is a diagram showing a sixth embodiment of the present invention and particularly shows a configuration that uses a P-channel transistor 310 as the rectification element 303 instead of a diode in the driving circuit shown in FIG. 4.

The back gate of the P-channel transistor 310 is connected to the driver 302 and the level shift driver 306. Therefore, even in a case where the voltage VBST is higher than the input voltage VH, the circuit controls the gate of the P-channel transistor 310 so that the P-channel transistor 310 can be turned off.

The circuit shown in FIG. 8 is provided with the comparator 309 having the non-inverting input connected to the voltage VBST and the inverting input connected to the input voltage VH. The circuit controls the gate of the P-channel transistor with the output of the comparator 309, whereby the P-channel transistor is turned on when the voltage VBST is lower than the input voltage VH and turned off when the voltage VBST is higher than the input voltage VH.

(Modification of Sixth Embodiment)

As in the case of the circuit shown in FIG. 7B, it is also possible to use, instead of the comparator 309 shown in FIG. 8, the inverter that uses the voltage VBST as a positive-side power supply, the voltage of the connection node LX as a negative-side power supply, and the input voltage VH as an input. The circuit controls the gate of the P-channel transistor with the output of the inverter, whereby the P-channel transistor is turned on when the voltage VBST is lower than the voltage calculated by the input voltage VH+(the voltage VBST−the voltage of the connection node LX) and turned off when the voltage VBST is higher than the voltage calculated by the input voltage VH+(the voltage VBST−the voltage of the connection node LX). The threshold of the inverter is different from that of the comparator. However, no problem arises in the circuit since it outputs a rectangular waveform as in the modification of the fifth embodiment.

### Seventh Embodiment

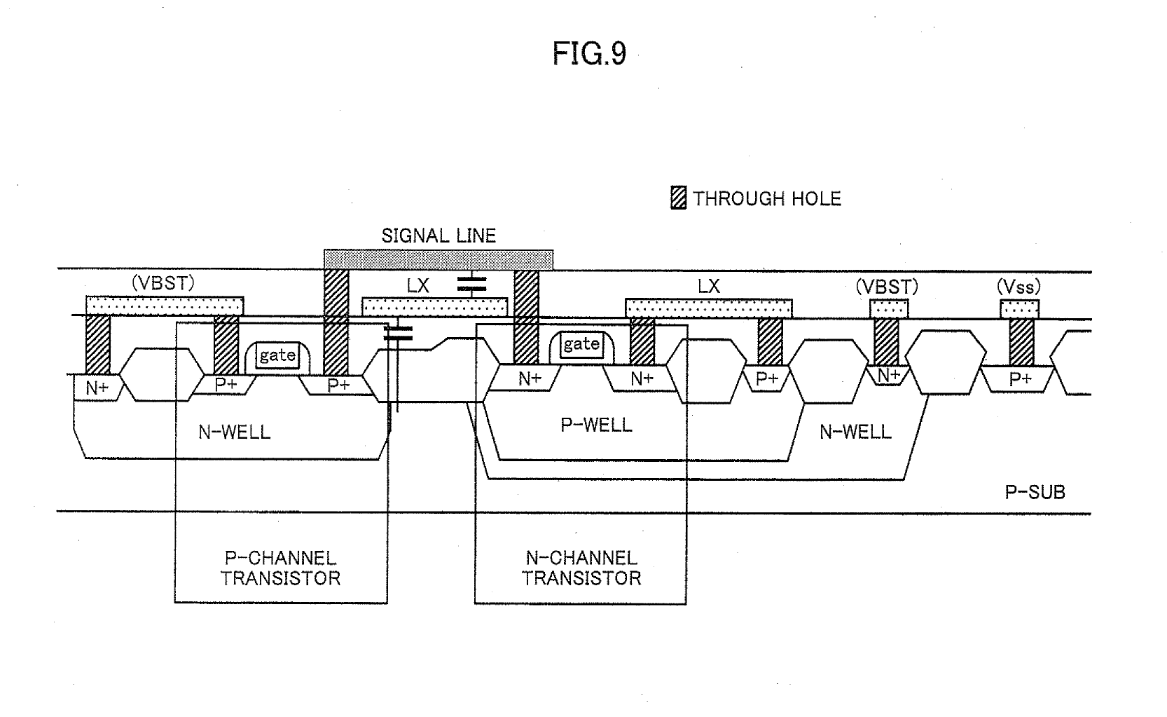

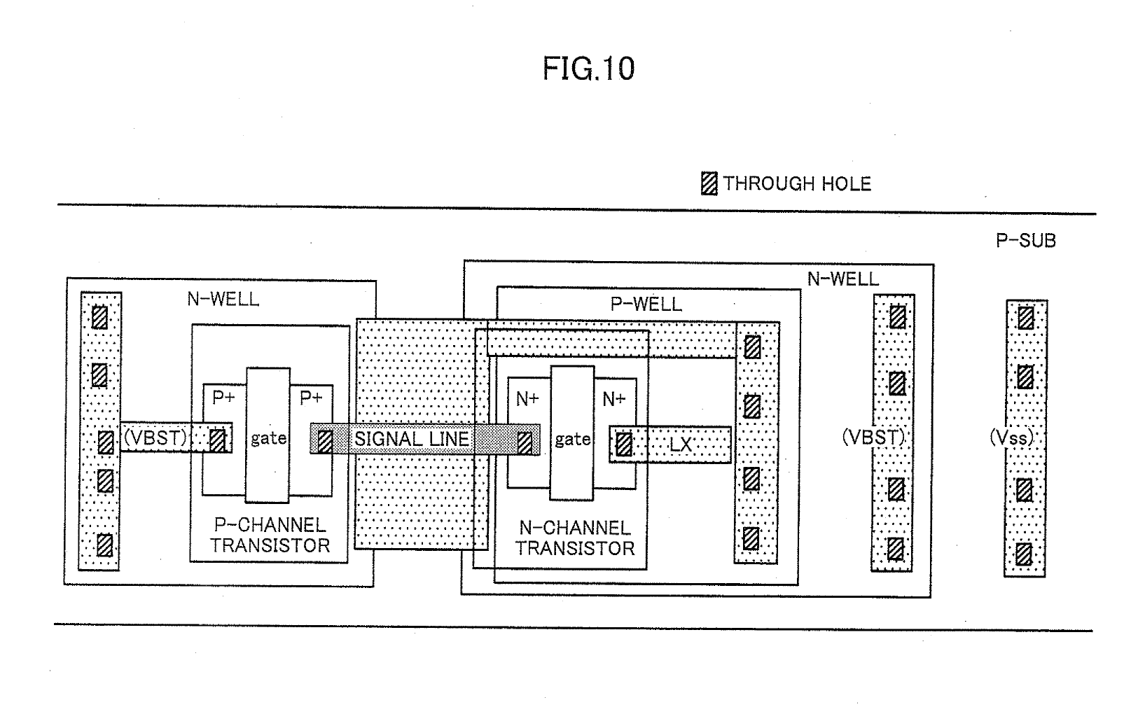

A description is given of a seventh embodiment of the present invention. FIG. 9 is a cross-sectional view of a CMOS structure for describing the seventh embodiment, and FIG. 10 is a view (top view) as seen from the top surface of the CMOS structure shown in FIG. 9.

As shown in FIGS. 9 and 10, the first driving circuit 10 and the first power supply circuit 30 are connected to the connection node LX and the output VBST of the first power supply circuit 30, respectively. The connection node LX performs a switching operation between the voltages HI and LO with the switching element M1. The voltage Vss of a semiconductor substrate Psub and the SIGNAL LINE of a circuit arranged between the connection node LX and the output VBST of the first power supply circuit 30 are coupled by parasitic capacitor and shielded by the connection node LX so as not to cause noise.

Since the voltage of the connection node LX becomes a reference when seen from the first driving circuit 10 and the first power supply circuit 30, the parasitic capacitance between the connection node LX and the SIGNAL LINE does not cause noise.

FIG. 9 shows an example in which the SIGNAL LINE is shielded by the connection node LX. However, the same effect can be obtained even in a case where the SIGNAL LINE is shielded by the first voltage VBST rather than the connection node LX.

### Eighth Embodiment

An eighth embodiment of the present invention is an embodiment of a semiconductor device, in which the driving circuit described above, i.e., the respective circuit parts excluding the inductor L1 and the output capacitor Co in FIGS. 3 through 8 are integrated together on the same semiconductor chip. Note that the respective circuit parts excluding the switching transistor M1 and/or the diode D1, the inductor L1, and the output capacitor Co may be integrated together on the same semiconductor chip depending on circumstances.

### Ninth Embodiment

A ninth embodiment of the present invention refers to a case where the driving circuit described in the first through eighth embodiments is applied to a switching regulator. In the embodiments described above, the driving circuit according to the present invention is applied to the diode-rectification-type switching regulator that uses the diode D1 as a rectification element. However, it is of course possible to apply the driving circuit to a synchronous-rectification-type switching transistor that uses a FET instead of the rectification diode D1 and controls the on/off of the gate of the FET at an appropriate timing in synchronization with a clock so as to perform a rectification operation.

### Tenth Embodiment

The driving circuit, the semiconductor device, and the switching regulator described above can be applied to various electronic equipment (home electric appliances, audio goods, mobile electric devices, etc.) requiring constant voltage. In view of this, the electronic equipment according to the present invention includes any electronic equipment that incorporates the driving circuit, the semiconductor device, or the switching regulator (diode rectification type and synchronous rectification type) according to the embodiments described above.

As described above, the embodiments of the present invention can provide the following effects.

According to the embodiments of the present invention, even in a case where the output node of the driving circuit is maintained at high voltage and in a case where a switching frequency and the forward voltage drop Vf of the bootstrap diode are high, the power supply voltage can be stably supplied to the first driving circuit.

Further, in the configuration in which the high withstand voltage element and the low withstand voltage element are integrated together on the same semiconductor chip and the input voltage higher than the withstand voltage of the low withstand voltage element is input to the input terminal, the low withstand voltage element having high driving performance is applied to the circuit using the first voltage as the power supply, whereby the driving circuit can accelerate its speed and reduce its occupied area.

Further, the output node or the first voltage of the driving circuit fluctuates at high speed when seen from the semiconductor substrate. Therefore, coupling noise due to parasitic capacitance may be caused. However, since the signal between the first voltage and the output node is shielded by the first voltage or the output node at a manufacturing time, the coupling noise from the semiconductor substrate can be eliminated.

Moreover, the driving circuit can be integrated together on the same semiconductor chip to constitute the semiconductor device, and the driving circuit and the semiconductor device can be applied to the switching regulator, in particular, the diode-rectification-type switching regulator or the synchronous rectification switching regulator, or the various electronic equipment.

According to the embodiments of the present invention, it is possible to achieve the driving circuit capable of stably supplying the power supply of the driving circuit without being influenced by the fluctuation of an oscillation frequency, a discontinuous mode, and the fluctuation of a period at which the connection node is in the “LO” state. Further, it is also possible to achieve the semiconductor device having the driving circuit and the switching regulator and the electronic equipment having the driving circuit and the semiconductor device.

The present application is based on Japanese Priority Application No. 2010-155792 filed on Jul. 8, 2010, with the Japan Patent Office, the entire contents of which are hereby incorporated by reference.

1. A driving circuit comprising:
a switching element configured to be connected between an input terminal and an output node;
a first power supply circuit configured to generate a first voltage; and
a first driving circuit configured to drive the switching element with an output thereof using a voltage of the output node as a reference negative-side power supply voltage and the first voltage as a positive-side power supply voltage; wherein
the voltage of the output node is used as a reference negative-side power supply voltage of the first power supply.

2. The driving circuit according to claim 1, wherein the switching element is an N-channel MOSFET or an NPN transistor having an input terminal thereof connected to a drain or a collector and an output node thereof connected to a source or an emitter.

3. A driving circuit comprising:
a switching element configured to be connected between an input terminal and an output node
a first power supply circuit configured to generate a first voltage; and
a first driving circuit configured to drive the switching element an output thereof using a voltage of the output node as a reference negative side power supply voltage and the first voltage as a positive-side power supply voltage; wherein
the voltage of the output node is used as a reference negative-side power supply voltage of the first power supply; and wherein
the first power supply circuit includes
a driver configured to output the first voltage based on an input voltage from the input terminal,
a rectification element configured to be connected to the driver in series and prevent a reverse flow of a current when the first voltage is higher than the input voltage,
a reference voltage circuit configured to output a reference voltage using the voltage of the output node as a reference negative-side power supply voltage and the first voltage as a positive-side power supply voltage,
a feedback resistor configured to divide the first voltage and feed back a divided voltage to an error amplifier, and
the error amplifier configured to be supplied with the reference voltage and the voltage divided by the feedback resistor and control the first voltage with an output thereof.

4. The driving circuit according to claim 3, wherein the error amplifier uses the voltage of the output node as a reference negative-side power supply voltage and the first voltage as a positive-side power supply voltage.

5. The driving circuit according to claim 3, wherein the driver is a first N-channel depletion transistor.

6. The driving circuit according to claim 3, further comprising:
a level shift circuit configured to shift a voltage level of the first voltage.

7. The driving circuit ding to claim 6, wherein the level shift circuit is composed of a second N-channel depletion transistor having a gate thereof connected to an output of the error amplifier, a drain thereof connected a drain of a first N hannel depletion transistor forming the driver, and a source thereof connected to the output node via a resistor and connected to a gate of the first N-channel depletion transistor forming the driver.

8. The driving circuit according to claim 1, wherein
the first power supply circuit includes
a driver configured to output the first voltage based on an input voltage,
a rectification element configured to be connected to the driver in series and prevent a reverse flow of a current when the first voltage is higher than the input voltage, and
a series circuit configured to have one or more stages of a cascade diode-connected N-channel transistor and a resistor provided between the first voltage and the voltage of the output node so as to generate a signal for controlling the driver.

9. The driving circuit according to claim 8, further comprising:
a constant voltage circuit configured to have an output thereof connected to the first voltage via a bootstrap diode.

10. The driving circuit according to claim 8, further comprising:
a level shift circuit configured to shift a voltage level of the first voltage.

11. The driving circuit according to claim 10, wherein the level shift circuit is composed of a second N-channel depletion transistor having a gate thereof connected to an output of the series circuit, a drain thereof connected a drain of a first N-channel depletion transistor forming the driver, and a source thereof connected to the output node via a resistor and connected to a gate of the first N-channel depletion transistor forming the driver.

12. The driving circuit according to claim 8, further comprising:
plural stages of level shift circuits configured to shift a voltage level of the first voltage; wherein
the number of the stages of the N-channel transistor is equal to a sum of the number of the stages of the level shift circuits and the number of the stages of the driver in the series circuit.

13. The driving circuit according to claim 3, wherein
the first power supply circuit includes a capacitor configured to smoothen the first voltage.

14. The driving circuit according to claim 7, further comprising, instead of the rectification element:
a switching unit configured to switch, when the first voltage is higher than the input voltage, a back gate(s) of the first N-channel depletion transistor and/or the second N-channel depletion transistor so as to prevent the reverse flow of the current.

15. The driving circuit according to claim 14, wherein the switching unit is a comparator configured to compare the first voltage with the input voltage or an inverter configured to use the first voltage as a power supply and the input voltage as an input.

16. The driving circuit according to claim 3, wherein
the rectification element is a P-channel transistor configured to be connected between the first voltage and the input voltage and turned off when the first voltage is higher than the input voltage.

17. The driving according to claim 3, wherein
the rectification element is a diode configured to have an anode thereof connected to the input voltage, have a cathode thereof connected to the first voltage, and be turned off when the first voltage is higher than the input voltage.

18. The driving circuit according to claim 1, wherein
a high withstand voltage element and a low withstand voltage element are integrated together on a same semiconductor chip,
the input voltage is set to be higher than or equal to a withstand voltage of the low withstand voltage element and less than or equal to a withstand voltage of the high withstand voltage element,
the first voltage is set to be less than or equal to the withstand voltage of the low withstand voltage element,
a circuit using the first voltage as a power supply is composed of the low withstand voltage element, and
the switching element is composed of the high withstand voltage element.

19. The driving circuit according to claim 1, wherein
a signal of a circuit arranged between the first voltage and the output node is shielded by the first voltage or the voltage of the output node.

20. A semiconductor device for use in a driving circuit of a switching regulator, comprising:
a switching element configured to be connected between an input terminal and an output node;
a first power supply circuit configured to generate a first voltage; and
a first driving circuit configured to drive be switching element with an output thereof using a voltage of the output node as a reference negative-side power supply voltage and the first voltage as a positive-side power supply voltage; wherein
the voltage of the output node is used as a reference negative-side power supply voltage of the first power supply.

21-24. (canceled)
